(19) United States
(12) Patent Application Publication
(10) Pub. No.: US 2012/0217961 A1
(43) Pub. Date: Aug. 30, 2012

(54) MAGNETIC SENSOR

(75) Inventors: Hideto ANDO, Niigata-ken (JP); Shinji SUGIHARA, Niigata-ken (JP); Takafumi NOGUCHI, Tokyo (JP)

(73) Assignee: ALPS ELECTRIC CO., LTD., Tokyo (JP)

(21) Appl. No.: 13/465,954

(22) Filed: May 7, 2012

Related U.S. Application Data
(63) Continuation of application No. PCT/JP2011/050529, filed on Jan. 14, 2011.

(30) Foreign Application Priority Data
Jan. 20, 2010 (JP) 2010-009608
Aug. 11, 2010 (JP) 2010-179911

(51) Int. Cl. G01R 33/02

(52) U.S. Cl. 324/252

(57) ABSTRACT

A magnetic sensor includes a plurality of magnetoresistance effect elements and soft magnetic bodies. Each of the magnetoresistance effect elements is formed by stacking a magnetic layer and a non-magnetic layer on a substrate so as to exhibit a magnetoresistance effect. The magnetoresistance effect element is configured such that element portions and electrode layers are alternately disposed. A soft magnetic body is disposed on one and the other sides of each of the element portions in the Y direction, and the soft magnetic bodies are displaced from each other in the X direction. With this arrangement, an external magnetic field applied in the X1 direction is changed into an external magnetic field in the Y direction when passing through the soft magnetic bodies, and the changed external magnetic field flows into the element portions.

### CLAIM OF PRIORITY

This application is a Continuation of International Application No. PCT/JP2011/050529 filed on Jan. 14, 2011, which claims benefit of Japanese Patent Application No. 2010-009608 filed on Jan. 20, 2010 and No. 2010-179911 filed on Aug. 11, 2010. The entire contents of each application noted above are hereby incorporated by reference.

### BACKGROUND OF THE INVENTION

1. Field of the Invention

The present invention relates to a magnetic sensor including magnetoresistance effect elements whose values of electrical resistances change when an external magnetic field is applied to the magnetoresistance effect elements.

2. Description of the Related Art

A magnetic sensor using a magnetoresistance effect element may be used as, for example, a geomagnetic sensor for detecting geomagnetism, integrated into a portable device, such as a cellular telephone.

For example, Japanese Unexamined Patent Application Publication No. 2006-66821 discloses an invention concerning a magnetic sensor including a magnetoresistance effect element and a permanent magnet layer. In this invention, the magnetization directions of free magnetic layers forming the magnetoresistance effect element are caused to be oriented in the same direction due to the application of a bias magnetic field from the permanent magnet layer.

When an external magnetic field is applied to a magnetoresistance effect element, the magnetization directions of free magnetic layers are changed to the direction of the external magnetic field. As a result, the value of the electrical resistance of the magnetoresistance effect element varies, and the external magnetic field can be detected on the basis of a change in the resistance value. Accordingly, it is necessary that the magnetoresistance effect element exhibit high magnetic sensitivity by ensuring that an external magnetic field is correctly applied to the magnetoresistance effect element.

In a magnetic sensor forming a bridge circuit including a plurality of magnetoresistance effect elements, it is necessary to decrease the differences among the temperature coefficients of resistance (TCRs) of the individual magnetoresistance effect elements in order to make the midpoint potentials uniform.

### SUMMARY OF THE INVENTION

The present invention has been made in order to solve the above-described problems. The present invention provides a magnetic sensor including magnetoresistance effect elements that ensure that an external magnetic field is correctly applied to the magnetoresistance effect elements.

According to an aspect of the invention, there is provided a magnetic sensor including: a magnetoresistance effect element configured to be formed by stacking a magnetic layer and a non-magnetic layer on a substrate so as to exhibit a magnetoresistance effect; and soft magnetic bodies configured to change a direction of an external magnetic field applied from a direction orthogonal to a direction of a sensitivity axis of the magnetoresistance effect element to the direction of the sensitivity axis and to supply the external magnetic field to the magnetoresistance effect element, the soft magnetic bodies being disposed so as not to be in contact with the magnetoresistance effect element. A Y direction of the magnetoresistance effect element is the direction of the sensitivity axis, and the soft magnetic bodies are each disposed on one side and the other side of the magnetoresistance effect element in the Y direction, among the soft magnetic bodies, a first soft magnetic body disposed on the one side of the magnetoresistance effect element and a second soft magnetic body disposed on the other side of the magnetoresistance effect element being displaced from each other in an X direction, which is orthogonal to the Y direction, so that the direction X of an external magnetic field applied from the X direction is changed to the Y direction between the first and second soft magnetic bodies and the external magnetic field flows into the magnetoresistance effect element. The magnetoresistance effect element includes an element linked body extending in the X direction, the element linked body including a plurality of element portions disposed with a space between the element portions in the X direction and an electrode layer disposed between the element portions, a soft magnetic body being disposed on each of one side and the other side of each of the element portions so that the soft magnetic bodies disposed on the one side and the other side of each of the element portions are displaced from each other in the X direction.

With this configuration, it is ensured that an external magnetic field correctly and effectively flows into the magnetoresistance effect element in the direction of the sensitivity axis. It is thus possible to provide a magnetic sensor that exhibits high magnetic sensitivity. It is also ensured that an external magnetic field correctly flows into each element portion in the direction of the sensitivity axis.

The first and second soft magnetic bodies may be displaced from each other in the X direction so that the first and second soft magnetic bodies do not oppose each other in the Y direction.

The first and second soft magnetic bodies may each include an end portion at which the direction of the external magnetic field is changed to the direction of the sensitivity axis between the first and second soft magnetic bodies, the end portion of the first soft magnetic body including an X1 end surface facing in an X1 direction, the X1 end surface being positioned, in an X2 direction, so as to be spaced apart from an X1 side edge portion of a first side surface, the first side surface being the one side of the magnetoresistance effect element, the end portion of the second soft magnetic body including an X2 end surface facing in the X2 direction, the X2 end surface being positioned, in the X1 direction, so as to be spaced apart from an X2 side edge portion of a second side surface, the second side surface being the other side of the magnetoresistance effect element.

The X1 end surface of the first soft magnetic body may be positioned on a line that extends in the Y direction from an X-direction-widthwise center of the first side surface of the magnetoresistance effect element, and the X2 end surface of the second soft magnetic body may be positioned on a line that extends in the Y direction from an X-widthwise center of the second side surface of the magnetoresistance effect element.

With this arrangement, the resistance to a disturbance magnetic field can be effectively improved.

When one side in the X direction is taken to be a front side and the other side in the X direction is taken to be a back side, a front end portion of a soft magnetic body disposed on the one side of each of the element portions may oppose the element portion in the Y direction, and a back end portion of a soft magnetic body disposed on the other side of each of the element portions may oppose the element portion in the Y direction, or the back end portion of a soft magnetic body disposed on the one side of each of the element portions may oppose the element portion in the Y direction, and the front end portion of a soft magnetic body disposed on the other side of each of the element portions may oppose the element portion in the Y direction.

The element linked body may be provided in a plurality, the plurality of element linked bodies being disposed with a space between the element linked bodies in the Y direction, the element linked bodies being formed in a meandering shape by connecting end portions of the element linked bodies to each other, and the soft magnetic bodies may be disposed between the element linked bodies with a space between the soft magnetic bodies in the X direction, each of the soft magnetic bodies being used for the element linked bodies positioned adjacent to each other.

With this arrangement, the space between the element linked bodies in the Y direction can be decreased, thereby implementing a reduction in the size of the magnetic sensor.

The magnetoresistance effect element may include a plurality of element portions disposed with a space between the element portions in the Y direction and hard bias layers positioned between the element portions so as to connect the element portions, and the hard bias layers may be disposed alternately between X1 end portions of the element portions and X2 end portions of the element portions so that a bias magnetic field applied from the X direction flows into the element portions and so that a direction of the bias magnetic field flowing into one of the element portions connected to each other with the hard bias layer is opposite to a direction of the bias magnetic field flowing into the other one of the element portions connected to each other with the hard bias layer, and a soft magnetic body may be disposed on each of one side and the other side of each of the element portions in the Y direction so that the soft magnetic bodies disposed on the one side and the other side of each of the element portions are displaced from each other in the X direction. In this case, the X1 end portions and the X2 end portions of the element portions may be obliquely tilted from extending in the Y direction so as to be tilted toward the X direction. With this arrangement, the linearity of output characteristics can be improved.

When one side in the X direction is taken to be a front side and the other side in the X direction is taken to be a back side, a front end portion of a soft magnetic body disposed on the one side of each of the element portions may oppose the element portion in the Y direction, and a back end portion of a soft magnetic body disposed on the other side of each of the element portions may oppose the element portion in the Y direction, or the back end portion of a soft magnetic body disposed on the one side of each of the element portions may oppose the element portion in the Y direction, and the front end portion of a soft magnetic body disposed on the other side of each of the element portions may oppose the element portion in the Y direction.

The element linked body may be provided in a plurality, the plurality of element linked bodies extending in the Y direction and being disposed with a space between the element linked bodies in the X direction, each of the plurality of element linked bodies including the element portions and the hard bias layers, the element linked bodies being formed in a meandering shape by connecting end portions of the element linked bodies to each other, and the plurality of soft magnetic bodies may be disposed between the element linked bodies, each of the soft magnetic bodies being used for the element linked bodies positioned adjacent to each other.

The magnetoresistance effect element may include an element linked body, the element linked body including a plurality of first element portions, a plurality of second element portions, and an electrode layer connecting the first and second element portions, the plurality of first element portions being disposed with a space between the first element portions in the X direction, the plurality of second element portions being displaced from the plurality of first element portions in the X direction and being disposed with a space between the second element portions in the Y direction, which is orthogonal to the X direction. The Y direction of the first and second element portions may be the direction of the sensitivity axis, and a soft magnetic body may be disposed on each of one and the other sides of each of the first and second element portions such that the soft magnetic body opposes the first or second element portion in the Y direction in a non-contact manner. The soft magnetic bodies disposed on the one side and the other side of each of the first and second element portions may be displaced from each other in the X direction so that a direction of an external magnetic field applied from the X direction is changed to the Y direction between the soft magnetic bodies and the external magnetic field flows into each of the first and second element portions.

The element linked body may be provided in a plurality, the plurality of element linked bodies being disposed with a space between the element linked bodies in the Y direction, end portions of the element linked bodies being connected to each other, and, between the element linked bodies, the soft magnetic bodies may be disposed with a space between the soft magnetic bodies in the X direction, each of the soft magnetic bodies being used for the element linked bodies positioned adjacent to each other.

With this arrangement, the space between the element linked bodies in the Y direction can be decreased, thereby implementing a reduction in the size of the magnetic sensor.

The magnetoresistance effect element may be provided in a plurality. The magnetic sensor may be formed by a bridge circuit including first, second, third, and fourth magnetoresistance effect elements. The first and third magnetoresistance effect elements may be connected to an input terminal, while the second and fourth magnetoresistance effect elements are connected to a ground terminal. A first output terminal may be connected between the first and second magnetoresistance effect elements, while a second output terminal may be connected between the third and fourth magnetoresistance effect elements. The first, second, third, and fourth magnetoresistance effect elements may be formed by an identical film structure and pinned magnetization directions of pinned magnetic layers provided for the individual first, second, third, and fourth magnetoresistance effect elements may be identical. An arrangement of the soft magnetic bodies with respect to the first and fourth magnetoresistance effect elements may be different from an arrangement of the soft magnetic bodies with respect to the second and third magnetoresistance effect elements so that a direction of an external magnetic field flowing into the first and fourth magnetoresistance effect elements is opposite to a direction of an external magnetic field flowing into the second and third magnetoresistance effect elements.

With this arrangement, the differences in the TCRs of the magnetoresistance effect elements can be decreased, and the difference between the midpoint potential of the first output terminal and that of the second output terminal can be decreased.

A Y direction of each of the first, second, third, and fourth magnetoresistance effect elements may be the direction of the sensitivity axis, and a soft magnetic body may be disposed on each of one side and the other side of each of the first, second, third, and fourth magnetoresistance effect elements in the Y direction, and a soft magnetic body disposed on the one side of each of the first, second, third, and fourth magnetoresistance effect elements and a soft magnetic body disposed on the other side of each of the first, second, third, and fourth magnetoresistance effect elements may be displaced from each other in the X direction so that the X direction of an external magnetic field applied from the X direction is changed to the Y direction between the soft magnetic bodies disposed on the one and the other sides of each of the first, second, third, and fourth magnetoresistance effect elements and the external magnetic field flows into each of the first, second, third, and fourth magnetoresistance effect element. A direction in which the soft magnetic bodies disposed on the one side and the other side of each of the first and fourth magnetoresistance effect elements are displaced from each other with respect to the first and fourth magnetoresistance effect elements may be opposite to a direction in which the soft magnetic bodies disposed on the one side and the other side of each of the second and third magnetoresistance effect elements are displaced from each other with respect to the second and third magnetoresistance effect elements.

With this configuration, without changing the film configuration, the direction of an external magnetic field that flows into the first and fourth magnetoresistance effect elements can be made opposite to that of an external magnetic field that flows into the second and third magnetoresistance effect elements.

More specifically, each of the first, second, third, and fourth magnetoresistance effect elements may include an element linked body extending in the X direction, the element linked body including a plurality of element portions disposed with a space between the element portions in the X direction and an electrode layer disposed between the element portions. When one side in the X direction is taken to be a front side and the other side in the X direction is taken to be a back side, in the first and fourth magnetoresistance effect elements, a front end portion of a soft magnetic body disposed on the one side of each of the element portions forming the first and fourth magnetoresistance effect elements may oppose the element portion in the Y direction, while a back end portion of a soft magnetic body disposed on the other side of each of the element portions may oppose the element portion in the Y direction, and in the second and third magnetoresistance effect elements, the back end portion of a soft magnetic body disposed on the one side of each of the element portions forming the second and third magnetoresistance effect elements may oppose the element portion in the Y direction, while the front end portion of a soft magnetic body disposed on the other side of each of the element portions may oppose the element portion in the Y direction.

### BRIEF DESCRIPTION OF THE DRAWINGS

FIG. 1 is a plan view schematically illustrating a magnetic sensor according to an embodiment;

FIG. 2 is a circuit diagram illustrating a magnetic sensor;

FIG. 3A is an enlarged partial plan view illustrating a portion of the magnetic sensor designated by IIIA in FIG. 1;

FIG. 3B is an enlarged plan view illustrating a portion shown in FIG. 3A;

FIG. 4 is an enlarged partial plan view illustrating a portion of the magnetic sensor designated by IV in FIG. 1;

FIG. 5 is an enlarged view of a longitudinal section illustrating the magnetic sensor taken along line V-V in FIG. 3A and as viewed from the direction of the arrow;

FIG. 6 is a partial view of a longitudinal section illustrating a magnetoresistance effect element (element portion) in the present embodiment;

FIG. 7A is an enlarged view of a longitudinal section illustrating the magnetic sensor taken along line VIIA-VIIA in FIG. 3A and as viewed from the direction of the arrow;

FIG. 7B illustrates a modified example of the magnetic sensor shown in FIG. 7A;

FIG. 8 illustrates a modified example illustrating a configuration different from the configuration of the magnetoresistance effect elements shown in FIGS. 3A and 4;

FIG. 9 is an enlarged partial plan view illustrating a portion of a magnetic sensor according to another embodiment;

FIGS. 10A and 10B are enlarged partial plan views illustrating a portion of the magnetic sensor shown in FIG. 9; and

FIG. 11 is a graph illustrating a result of experiment concerning the resistance to a disturbance magnetic field.

### DESCRIPTION OF THE PREFERRED EMBODIMENTS

An embodiment of the present invention will be described below with reference to the accompanying drawings. A magnetic sensor S including magnetoresistance effect elements according to the present embodiment is configured as a geomagnetic sensor integrated into a portable device, such as a cellular telephone.

In the drawings, the X axis and the Y axis indicate two directions which are orthogonal to each other in the horizontal plane, and the Z axis indicates a direction orthogonal to the horizontal plane. Assume that the X1-X2 direction is a front-back direction and that the X1 direction is taken to be the front side and the X2 direction is taken to be the back side.

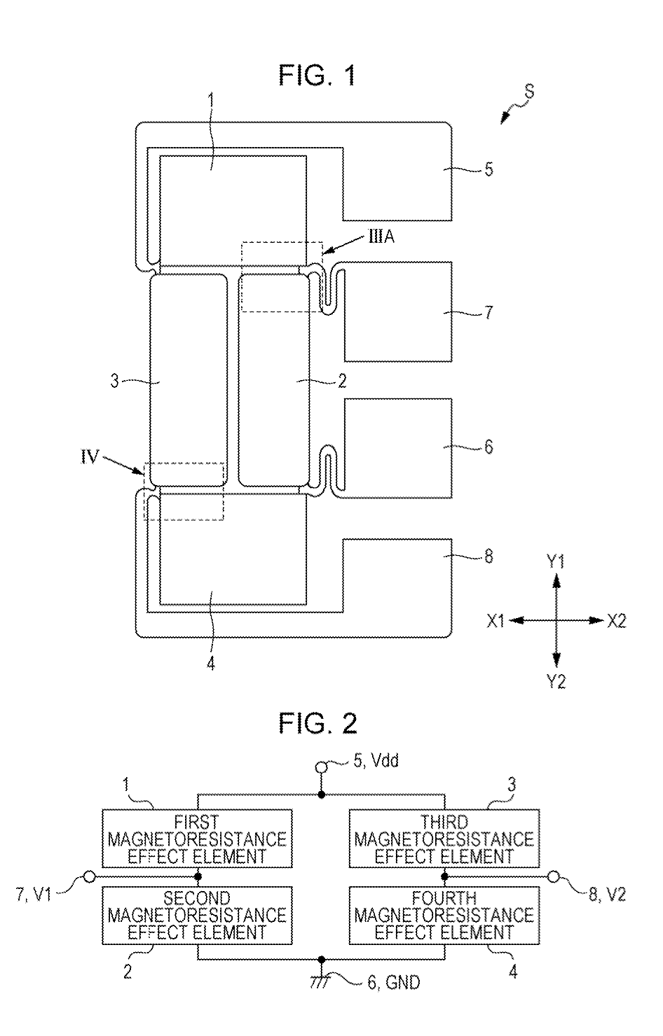

FIG. 1 is a schematic view (plan view) illustrating a magnetic sensor S according to the present embodiment. FIG. 2 is a circuit diagram of the magnetic sensor S.

The magnetic sensor S includes, as shown in FIGS. 1 and 2, a first magnetoresistance effect element 1, a second magnetoresistance effect element 2, a third magnetoresistance effect element 3, and a fourth magnetoresistance effect element 4. The first through fourth magnetoresistance effect elements 1 through 4 are formed in a meandering shape in which element portions and electrode layers are alternately connected to one another, which will be discussed later. In FIG. 1, the shapes of the first through fourth magnetoresistance effect elements 1 through 4 are shown in a simplified form.

As shown in FIGS. 1 and 2, the first and third magnetoresistance effect elements 1 and 3 are connected to an input terminal (Vdd) 5, while the second and fourth magnetoresistance effect elements 2 and 4 are connected to a ground terminal (GND) 6. A first output terminal (V1) 7 is connected between the first and second magnetoresistance effect elements 1 and 2. A second output terminal (V2) 8 is connected between the third and fourth magnetoresistance effect elements 3 and 4.

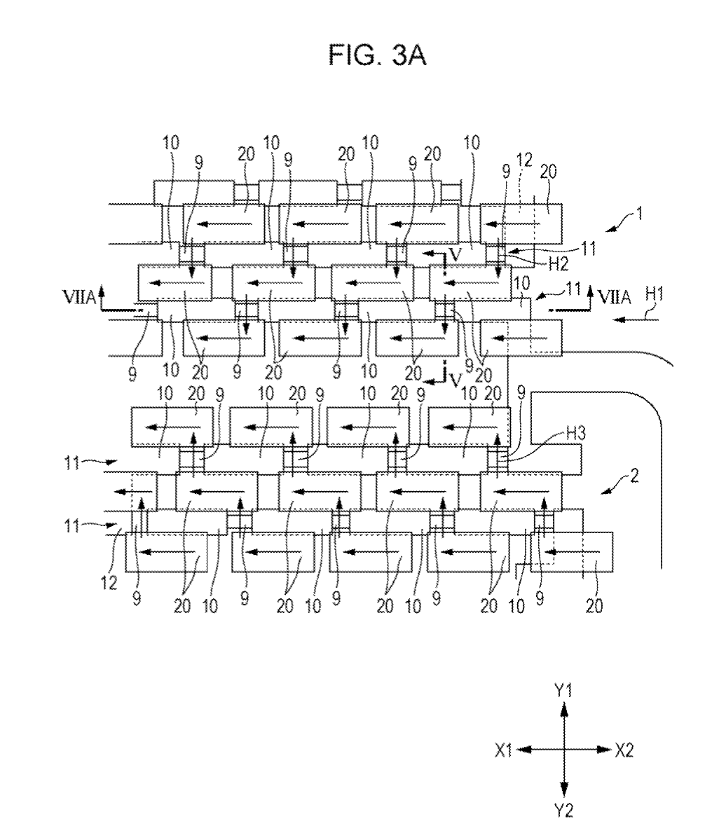

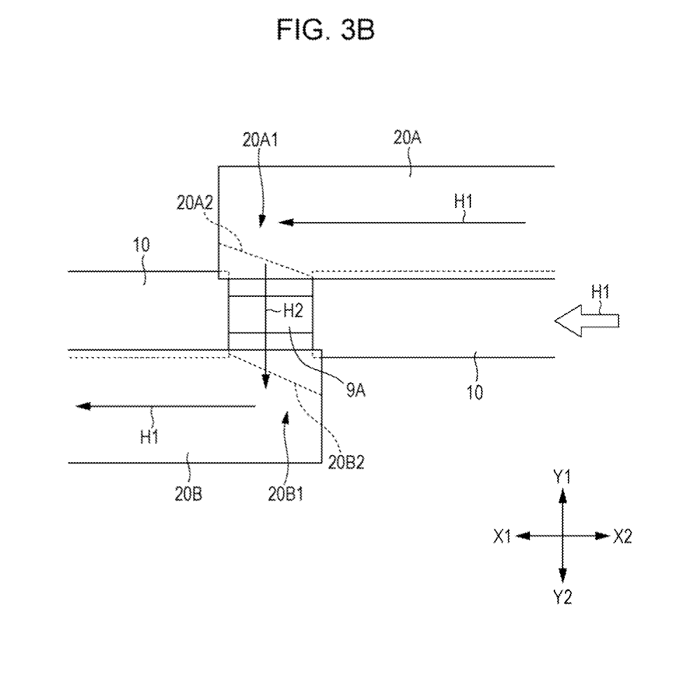

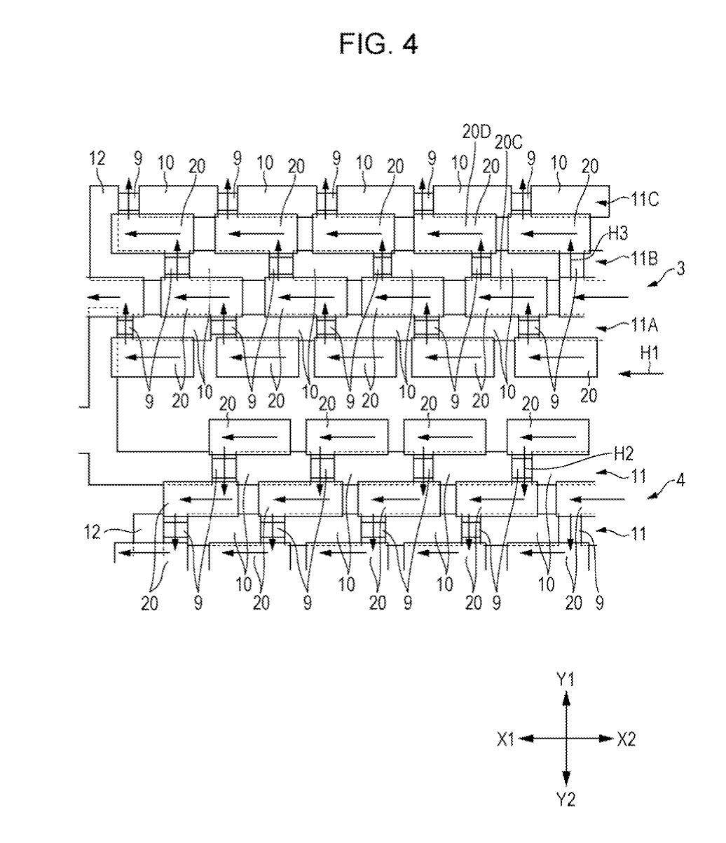

FIG. 3A is an enlarged partial plan view illustrating a portion of the magnetic sensor designated by IIIA in FIG. 1. FIG. 4 is an enlarged partial plan view illustrating a portion of the magnetic sensor designated by IV in FIG. 1. The first magnetoresistance effect element 1 includes, as shown in FIG. 3A, a plurality of element portions 9 disposed in the X direction with spaces therebetween and an electrode layer 10 disposed between adjacent element portions 9. As shown in FIG. 3A, the element portions 9 and the electrode layer 10 are linked to one another, thereby forming an element linked body 11 extending in the X direction. A plurality of element linked bodies 11 are disposed in the Y direction with spaces therebetween. Then, the end portions of the element linked bodies 11 disposed in the X direction are connected to each other by use of a conductive connecting layer 12. With this configuration, the first magnetoresistance effect element 1 is formed in a meandering shape.

The second magnetoresistance effect element 2 shown in FIG. 3A and the third and fourth magnetoresistance effect elements 3 and 4 shown in FIG. 4 are also formed in the same configuration as in the first magnetoresistance effect element 1.

FIG. 6 is a partial view of a longitudinal section illustrating a magnetoresistance effect element (element portion 9) in the present embodiment. The element portion 9 is formed, as shown in FIG. 6, by stacking an antiferromagnetic layer 33, a pinned magnetic layer 34, a non-magnetic layer 35, and a free magnetic layer 36 in this order from the bottom, and by covering the surface of the free magnetic layer 36 with a protective layer 37. The element portion 9 is formed by means of, for example, sputtering.

The antiferromagnetic layer 33 is made of an antiferromagnetic material, such as an iridium-manganese alloy (IrMn alloy). The pinned magnetic layer 34 is made of a soft magnetic material, such as a cobalt-iron alloy (CoFe alloy). The pinned magnetic layer 34 may preferably be formed in a multilayered ferrimagnetic structure. The non-magnetic layer 35 may be made of copper (Cu). The free magnetic layer 36 is formed of a soft magnetic material, such as a nickel-iron alloy (NiFe alloy). The protective layer 37 is made of, for example, tantalum (Ta). The multilayered configuration of the element portion 9 shown in FIG. 6 is an example only, and another multilayered configuration may be employed for the element portion 9.

In the element portion 9, the magnetization direction (P direction) of the pinned magnetic layer 34 is pinned due to antiferromagnetic coupling between the antiferromagnetic layer 33 and the pinned magnetic layer 34. As shown in FIG. 6, the pinned magnetization direction (P direction) of the pinned magnetic layer 34 is, for example, the Y1 direction. The pinned magnetization direction (P direction) of the pinned magnetic layer 34 is the direction of the sensitivity axis. On the other hand, the magnetization direction of the free magnetic layer 36 varies in accordance with an external magnetic field.

Assume that an external magnetic field is applied in the same direction as the pinned magnetization direction (P direction) of the pinned magnetic layer 34 and thereby causes the magnetization direction of the free magnetic layer 36 to shift to the direction of the external magnetic field. In this case, the pinned magnetization direction of the pinned magnetic layer 34 and the magnetization direction of the free magnetic layer 36 are substantially parallel with each other, thereby reducing the electrical resistance.

Assume that, in contrast, an external magnetic field is applied in the direction opposite to the pinned magnetization direction (P direction) of the pinned magnetic layer 34 and thereby causes the magnetization direction of the free magnetic layer 36 to shift to the direction of the external magnetic field. In this case, the pinned magnetization direction of the pinned magnetic layer 34 and the magnetization direction of the free magnetic layer 36 are substantially antiparallel with each other, thereby increasing the electrical resistance. The magnetoresistance effect element may be formed as a giant magnetoresistance (GMR) effect element. Alternatively, the magnetoresistance effect element may be formed as a tunnel magnetoresistance (TMR) effect element in which the non-magnetic layer 35 is formed as an insulating layer. The magnetoresistance effect element may be formed as an anisotropic magnetoresistance (AMR) effect element.

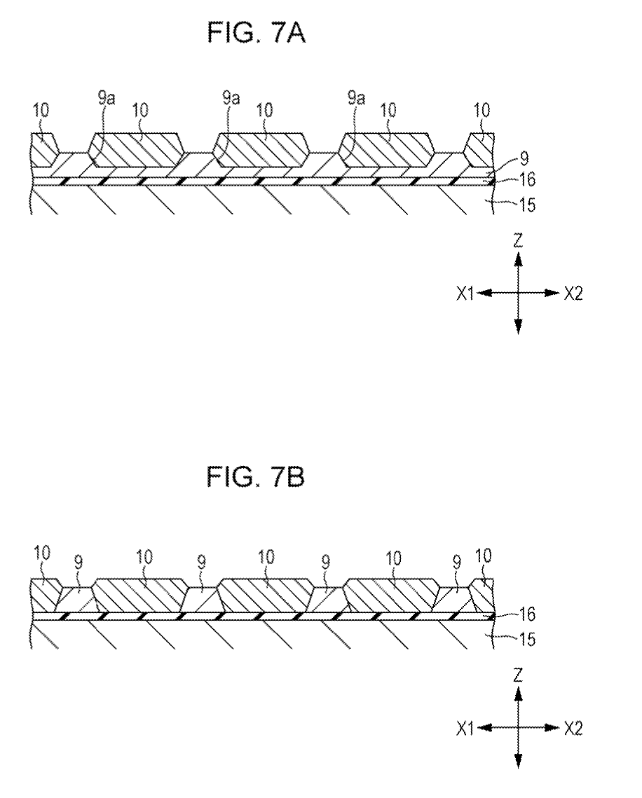

FIG. 7A is an enlarged view of a longitudinal section illustrating the magnetic sensor S taken along line VIIA-VIIA in FIG. 3A and as viewed from the direction of the arrow. The element portions 9 are formed, as shown in FIG. 7A, on a substrate 15 with an electrically insulating underlying layer 16 therebetween. The element portions 9 are formed such that they extend in the X direction. Recessed portions 9a are formed with spaces therebetween on top of the element portions 9, and an electrode layer 10 is formed in each of the recessed portions 9a. The recessed portions 9a shown in FIG. 7A are formed at such a depth as to divide the free magnetic layer 36 shown in FIG. 6 into separate portions in the X direction. The electrode layer 10 is, for example, a hard bias layer (permanent magnet layer), and supplies an X-direction bias magnetic field to the free magnetic layer 36. Accordingly, the magnetization of the free magnetic layer 36 is directed in the X direction in a magnetic-field free state. The hard bias layer is made of, for example, CoPt or CoPtCr, however, the material of the hard bias layer is not particularly restricted.

FIG. 7B illustrates a modified example of the magnetic sensor S shown in FIG. 7A. As an alternative to the magnetic sensor S shown in FIG. 7A, the depth of the electrode layer 10 may be formed greater than that shown in FIG. 7A. However, if the electrode layer 10 is a hard bias layer, it is preferable that the pinned magnetic layer 34 is not divided into some separate portions. The reason for this is as follows. If the pinned magnetic layer 34 is not divided into separate portions, it is less influenced by a bias magnetic field, and the fluctuations in the pinned magnetization direction (P direction) of the pinned magnetic layer 34 can be decreased, thereby improving the detection accuracy.

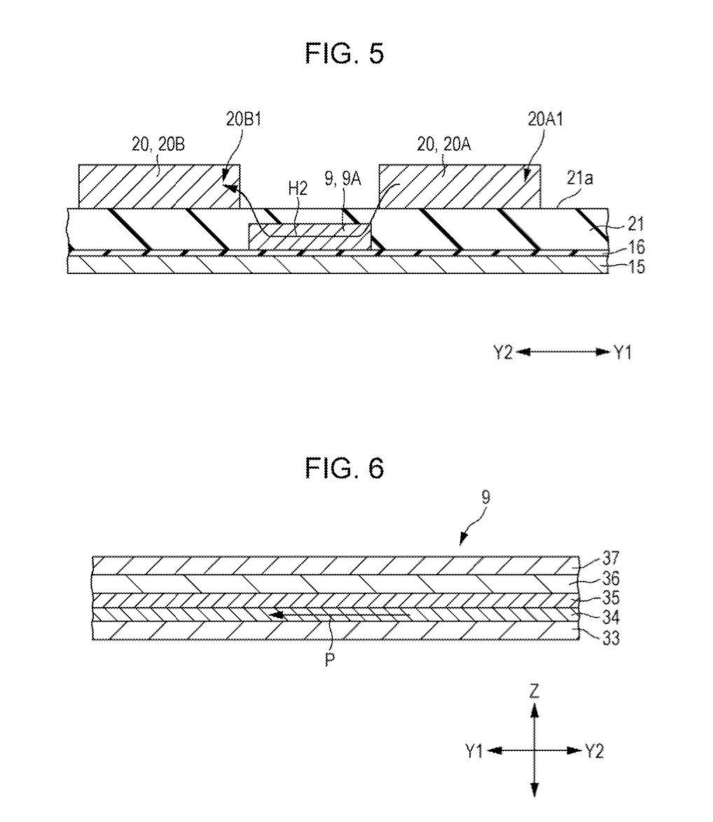

As shown in FIGS. 3A and 4, a soft magnetic body 20 is disposed on each of one and the other sides of each of the element portion 9 in the Y direction (in the direction of the sensitivity axis). The soft magnetic body 20 is made of, for example, NiFe, CoFe, CoFeSiB, or CoZrNb. FIG. 5 is an enlarged view of a longitudinal section illustrating the magnetic sensor S taken along line V-V in FIG. 3A and as viewed from the direction of the arrow. As shown in FIG. 5, the soft magnetic body 20 is disposed such that it is not in contact with the element portion 9 with an insulating layer 21 therebetween. The insulating layer 21 is an electrically insulating layer, such as Al2O3 or SiO2. As shown in FIG. 5, a surface 21a of the insulating layer 21 may be flattened, or may be formed in a step-like manner, as in the portion between the element portion 9 and the underlying layer 16.

As shown in FIG. 3A, the soft magnetic bodies 20 are not in contact with each other. The soft magnetic bodies 20 disposed toward the Y1 direction with respect to the element portions 9 forming the first magnetoresistance effective element 1 are displaced in the X direction from the soft magnetic bodies 20 disposed toward the Y2 direction with respect to the element portions 9.

FIG. 3B is an enlarged plan view illustrating a portion shown in FIG. 3A. In FIG. 3B, one of the soft magnetic bodies 20 of a section taken along line V-V is designated by 20A, the other one of the soft magnetic bodies 20 of a section taken along line V-V is designated by 20B, and the element portion 9 of a section taken along line V-V is designated by an element portion 9A.

As shown in FIG. 3B, a front end portion (X1 side) 20A1 of the soft magnetic body 20A disposed on the Y1 side of the element portion 9A opposes the element portion 9A in the Y direction. Also, as shown in FIG. 3B, a back end portion (X2 side) 20B1 of the soft magnetic body 20B disposed on the Y2 side of the element portion 9A opposes the element portion 9A in the Y direction.

As shown in FIGS. 3A and 3B, the soft magnetic bodies 20 have the same configuration, and are formed in a rectangular shape having a length in the X direction and a width in the Y direction. The soft magnetic bodies 20 opposing each other at the ends of the element portion 9 in the Y direction are displaced from each other in the X direction. Accordingly, the end portions of the soft magnetic bodies 20 in the X direction are not aligned in the Y direction but are displaced from each other.

Assume that an external magnetic field H1 is applied to the magnetic sensor S in the X1 direction. In FIGS. 3A, 3B, and 4, the directions of the external magnetic field which enters the soft magnetic bodies 20 or leaks between the soft magnetic bodies 20 are indicated by arrows. The external magnetic field H1 enters, as shown in FIGS. 3A and 3B, from the X2 side of the soft magnetic bodies 20. In this case, as shown in FIGS. 3B and 5, an external magnetic field H2 flows from the front end portion 20A1 of one of the soft magnetic bodies 20 that oppose each other with the element portion 9A therebetween to the back end portion 20B1 of the other soft magnetic body 20. The direction of the external magnetic field H2 is the Y direction (direction of the sensitivity axis). That is, the direction of the external magnetic field H1 which enters each of the soft magnetic bodies 20 from the X direction is changed to the direction of the sensitivity axis when it passes through the soft magnetic body 20, and then acts on the soft magnetic body 20.

In this embodiment, the soft magnetic bodies 20A and 20B which oppose each other with the element portion 9A therebetween are displaced from each other in the X direction. Particularly, the front end portion 20A1 of one soft magnetic body 20 and the back end portion 20B1 of the other soft magnetic body 20 are displaced from each other in the X direction such that they oppose each other with the element portion 9A therebetween. With this configuration, the magnetic intensity of the external magnetic field H2 whose direction has been changed to the direction of the sensitivity axis (Y direction) between the soft magnetic bodies 20A and 20B can be effectively increased at the position of the element portion 9A. Accordingly, the external magnetic field H2 oriented in the direction of the sensitivity axis (Y direction) can appropriately act on the element portion 9A. Additionally, as shown in FIG. 3B, a side surface 20A2 of the front end portion 20A1 of the soft magnetic body 20A facing toward the element portion 9A and a side surface 20B2 of the back end portion 20B1 of the soft magnetic body 20B facing toward the element portion 9A are tilted, whereby the magnetic intensity of the external magnetic field H2 whose direction has been changed from the X direction to the Y direction can be more effectively increased. It is preferable that the side surfaces 20A2 and 20B2 are tilted substantially in the same direction.

The external magnetic field H2 shown in FIG. 3B acts on the element portion 9A, and then, the magnetization direction of the free magnetic layer 36 is changed to the direction of the external magnetic field H2. As shown in FIG. 6, the pinned magnetization direction (P direction) of the pinned magnetic layer 34 is the Y1 direction, while the magnetization direction of the free magnetic layer 36 is the Y2 direction, which is the direction of the external magnetic field H2. Accordingly, the magnetization of the pinned magnetic layer 34 and the magnetization of the free magnetic layer 36 are antiparallel, and thus, the electrical resistance is maximized.

As shown in FIG. 3A, the soft magnetic bodies 20 are disposed on one and the other sides of each of the element portions 9 in the Y direction. In the first magnetoresistance effect element 1, the arrangement of such soft magnetic bodies 20 with respect to the element portions 9 is uniform. Accordingly, the external magnetic field H2 oriented in the Y2 direction acts on all the element portions 9 forming the first magnetoresistance effect element 1. Thus, the electrical resistance values of all the element portions 9 are maximized, and accordingly, the electrical resistance value of the first magnetoresistance effect element 1 formed by connecting the element portions 9 in series with each other is maximized.

Meanwhile, as shown in FIG. 3A, an external magnetic field H3 oriented in the Y1 direction acts on the element portions 9 forming the second magnetoresistance effect element 2. This is because, in the second magnetoresistance effect element 2, the arrangement in which the soft magnetic body 20 positioned on the Y1 side of each element portion 9 is displaced in the X direction from the soft magnetic body 20 positioned on the Y2 side of the element portion 9 is opposite to that in the first magnetoresistance effect element 1. That is, the back end portion of the soft magnetic body 20 positioned on the Y1 side of each element portion 9 opposes the element portion 9 in the Y direction, while the front end portion of the soft magnetic body 20 positioned on the Y2 side of each element portion 9 opposes the element portion 9 in the Y direction. Accordingly, the external magnetic field H1, which enters each soft magnetic body 20 in the X1 direction, is changed to the external magnetic field H3 oriented in the Y1 direction between the soft magnetic bodies 20 which oppose each other with the element portion 9 therebetween. Then, the external magnetic field H3 changed in this manner acts on each element portion 9.

As shown in FIG. 3A, the external magnetic field H3 oriented in the Y1 direction acts on each element portion 9 of the second magnetoresistance effect element 2, thereby causing the magnetization direction of the free magnetic layer 36 to be oriented in the Y1 direction. As shown in FIG. 6, the pinned magnetization direction (P direction) of the pinned magnetic layer 34 is also the Y1 direction, and thus, the electrical resistance values of the element portions 9 forming the second magnetoresistance effect element 2 are minimized. Therefore, the electrical resistance value of the second magnetoresistance effect element 2 formed by connecting the element portions 9 in series with each other is minimized.

As shown in FIG. 4, the arrangement of the soft magnetic bodies 20 in the third magnetoresistance effect element 3 is the same as that in the second magnetoresistance effect element 2 shown in FIG. 3A. Accordingly, the electrical resistance value of the third magnetoresistance effect element 3 is minimized due to the application of the external magnetic field H1. As shown in FIG. 4, the arrangement of the soft magnetic bodies 20 in the fourth magnetoresistance effect element 4 is the same as that in the first magnetoresistance effect element 1 shown in FIG. 3A. Accordingly, the electrical resistance value of the fourth magnetoresistance effect element 4 is maximized due to the application of the external magnetic field H1.

The electrical resistance values of the first through fourth magnetoresistance effect elements 1 through 4 are shifted, as described above, thereby causing the first and second output terminals 7 and 8 of the bridge circuit shown in FIG. 2 to shift from the midpoint potential. It is thus possible to detect the external magnetic field H1 on the basis of voltage fluctuations of the first and second output terminals 7 and 8.

If the external magnetic field is applied from the X2 direction, the directions of the external magnetic field which act on the element portions 9 of the first through fourth magnetoresistance effect elements 1 through 4 become opposite to those shown in FIGS. 3A and 4. That is, the external magnetic field H3 oriented in the Y1 direction acts on the element portions 9 of the first and fourth magnetoresistance effect elements 1 and 4, while the external magnetic field H2 oriented in the Y2 direction acts on the element portions 9 of the second and third magnetoresistance effect elements 2 and 3. The voltage fluctuations of the first and second output terminals 7 and 8 also become opposite to those when the magnetic field is applied from the X1 direction. With this arrangement, the direction of the external magnetic field can be detected.

As described above, in the present embodiment, the magnetic sensor S includes the first through fourth magnetoresistance effect elements 1 through 4 (element portions 9) and the soft magnetic bodies 20 that can change the X direction of an external magnetic field to the direction of the sensitivity axis (Y direction). With this configuration, it is possible to ensure that an external magnetic field is correctly applied to the first through fourth magnetoresistance effect elements 1 through 4 (element portions 9) in the direction of the sensitivity axis. As a result, the magnetic sensor S can exhibit high magnetic sensitivity.

The first through fourth magnetoresistance effect elements 1 through 4 of this embodiment are configured such that the plurality of element linked bodies 11 formed by alternately linking the electrode portions 9 and the electrode layer 10 are connected to one another in a meandering shape. The provision of the electrode layer 10 is not essential. However, the provision of the electrode layer 10, which is a hard bias layer, makes it possible to ensure that the magnetization direction of the free magnetic layer 36 forming each element portion 9 is correctly oriented in the X direction. The electrode layer 10 does not have to be a hard bias layer, or the electrode layer 10 may be a multilayered structure of a hard bias layer and a low resistance layer having a resistance value lower than a hard bias layer.

In the third magnetoresistance effect element 3 shown in FIG. 4, a first element linked body 11A, a second element linked body 11B, and a third element linked body 11C are disposed in this order. Between the first and second element linked bodies 11A and 11B, the soft magnetic bodies 20, which are used for both the first and second element linked bodies 11A and 11B, are aligned in the X direction with a space therebetween. The positional relationship between the element linked bodies 11 and the element portions 9 will be described more specifically by taking a soft magnetic body 20C as an example. The back end portion (X2 side) of the soft magnetic body 20C opposes in the Y direction the element portion 9 forming the first element linked body 11A, while the front end portion (X1 side) of the soft magnetic body 20C opposes in the Y direction the element portion 9 forming the second element linked body 11B. The other soft magnetic bodies 20 positioned between the first and second element linked bodies 11A and 11B are also disposed with the above-described positional relationship.

Similarly, as shown in FIG. 4, between the second and third element linked bodies 11B and 11C, the soft magnetic bodies 20, which are used for both the second and third element linked bodies 11B and 11C, are aligned in the X direction with a space therebetween. The positional relationship between the element linked bodies 11 and the element portions 9 will be described more specifically by taking a soft magnetic body 20D as an example. The back end portion (X2 side) of the soft magnetic body 20D opposes in the Y direction the element portion 9 forming the second element linked body 11B, while the front end portion (X1 side) of the soft magnetic body 20D opposes in the Y direction the element portion 9 forming the third element linked body 11C. The other soft magnetic bodies 20 positioned between the second and third element linked bodies 11B and 11C are also disposed with the above-described positional relationship.

In this manner, by using a soft magnetic body 20 for two adjacent element linked bodies 11, the space between the element linked bodies 11 in the Y direction can be decreased, and the first through fourth magnetoresistance effect elements 1 through 4 can be efficiently arranged, thereby implementing a reduction in the size of the magnetic sensor S.

In this embodiment, as shown in FIGS. 1 and 2, a bridge circuit is formed by using the first through fourth magnetoresistance effect elements 1 through 4.

Then, as shown in FIGS. 3A and 4, the arrangement of the soft magnetic bodies 20 in the first and fourth magnetoresistance effect elements 1 and 4 is different from that in the second and third magnetoresistance effect elements 2 and 3 so that the direction of the external magnetic field H2 flowing into the first and fourth magnetoresistance effect elements 1 and 4 becomes opposite to the direction of the external magnetic field H3 flowing into the second and third magnetoresistance effect elements 2 and 3.

More specifically, in the first and fourth magnetoresistance effect elements 1 and 4, the front end portions (X1 side) of the soft magnetic bodies 20 disposed on the Y1 side of the element portions 9 oppose the element portions 9 in the Y direction. The back end portions (X2 side) of the soft magnetic bodies 20 disposed on the Y2 side of the element portions 9 oppose the element portions 9 in the Y direction.

Conversely, in the second and third magnetoresistance effect elements 2 and 3, the back end portions (X2 side) of the soft magnetic bodies 20 disposed on the Y1 side of the element portions 9 oppose the element portions 9 in the Y direction. The front end portions (X1 side) of the soft magnetic bodies 20 disposed on the Y2 side of the element portions 9 oppose the element portions 9 in the Y direction.

In this embodiment, as shown in FIGS. 3A and 4, the external magnetic field H2 that flows into the element portions 9 forming the first and fourth magnetoresistance effect elements 1 and 4 and the external magnetic field H3 that flows into the element portions 9 forming the second and third magnetoresistance effect elements 2 and 3 can be set in opposite directions. Accordingly, all the element portions 9 forming the first through fourth magnetoresistance effect elements 1 through 4 are formed with the same film configuration, and the pinned magnetization direction (P direction) of the pinned magnetic layers 34 of the element portions 9 can be set in the same direction.

Assume that the direction of the external magnetic field H2 that flows into the element portions 9 forming the first and fourth magnetoresistance effect elements 1 and 4 is the same as the direction of the external magnetic field H3 that flows into the element portions 9 forming the second and third magnetoresistance effect elements 2 and 3. In this case, it is necessary that the pinned magnetization direction (P direction) of the pinned magnetic layers 34 of the element portions 9 forming the first and fourth magnetoresistance effect elements 1 and 4 be antiparallel with that of the element portions 9 forming the second and third magnetoresistance effect elements 2 and 3. In order to implement this, it is necessary that the first and fourth magnetoresistance effect elements 1 and 4 and the second and third magnetoresistance effect elements 2 and 3 be separately formed and that the pinned magnetization directions be separately adjusted. Accordingly, it is more likely that the film thicknesses of the element portions 9 forming the first through fourth magnetoresistance effect elements 1 through 4 are different. As a result, it is more likely that TCRs are different among the first through fourth magnetoresistance effect elements 1 through 4.

In contrast, in this embodiment, the pinned magnetization direction (P direction) of the pinned magnetic layers 34 of all the first through fourth magnetoresistance effect elements 1 through 4 can be set in the same direction. Accordingly, all the element portions 9 forming the first through fourth magnetoresistance effect elements 1 through 4 can be formed simultaneously on the substrate, and the pinned magnetization direction can be adjusted with the same process for the first through fourth magnetoresistance effect elements 1 through 4. In this embodiment, therefore, each of the lengths, the widths, and the film thicknesses of the element portions 9 can be adjusted to be uniform with high precision. Thus, the difference in the TCR among the first through fourth magnetoresistance effect elements 1 through 4 can be decreased (ideally zero), and the difference between the midpoint potential of the first output terminal 7 and that of the second output terminal 8 can be decreased (ideally zero). As a result, the magnetic sensor S exhibits a high detection accuracy.

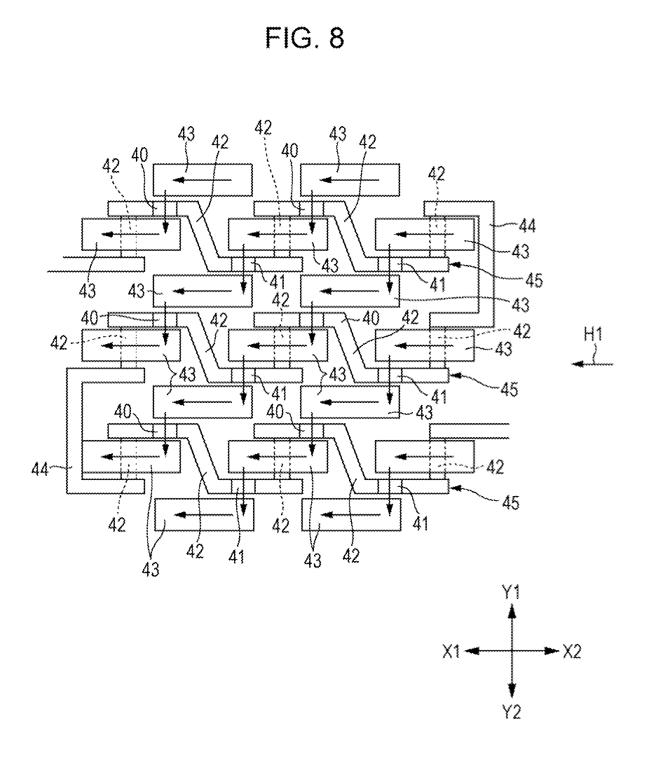

FIG. 8 is a partial plan view of a modified example illustrating a configuration different from the configuration of the magnetoresistance effect elements shown in FIGS. 3A and 4. The magnetic sensor shown in FIG. 8 has also a multilayered structure similar to that shown in FIG. 5. In FIG. 8, an insulating layer positioned between each of first and second element portions 40 and 41 and a soft magnetic body 43 is not shown.

In the modified example shown in FIG. 8, an element linked body 45 including a first element portion 40, a second element portion 41, and an electrode layer 42 is formed. A plurality of first element portions 40 are disposed with a space therebetween in the X direction. A plurality of second element portions 41 are displaced from the first element portions 40 in the X direction and are also disposed with a space therebetween in the Y direction, which is orthogonal to the X direction. The electrode layer 42 links the first electrode portion 40 and the second electrode portion 41.

The element linked bodies 11 forming the first through fourth magnetoresistance effect elements 1 through 4 shown in FIGS. 3A and 4 are formed such that they extend in parallel with the X direction. In contrast, the element linked bodies 45 shown in FIG. 8 bend along the X direction.

The element linked bodies 45 are disposed with a space therebetween in the Y direction, and the end portions (X direction) of the element linked bodies 45 are alternately connected to each other with a connecting layer 44 therebetween, thereby forming a single conduction path.

In the modified example shown in FIG. 8, as well as in the foregoing embodiment, the direction of the sensitivity axis of the first and second element portions 40 and 41 is the Y direction, and the pinned magnetization directions of the pinned magnetic layers 34 are uniform. As shown in FIG. 8, soft magnetic bodies 43 are disposed on one and the other sides of each of the first and second element portions 40 and 41 in the Y direction such that they are not in contact with the first element portion 40 or the second element portion 41. The soft magnetic bodies 43 positioned on one and the other sides of each of the first and second element portions 40 and 41 are displaced from each other in the X direction so that the X direction of the external magnetic field H1 is changed to the Y direction between the soft magnetic bodies 43 positioned on one and the other sides of each of the first and second element portions 40 and 41 and the external magnetic field H1 flows into the first or second element portion 40 or 41 in the Y direction. The positional relationship in which the soft magnetic bodies 43 are displaced from each other with respect to the first or second soft magnetic body 40 or 41 is similar to that shown in FIGS. 3A and 4.

The configuration shown in FIG. 8 is a configuration of, for example, the first and fourth magnetoresistance effect elements 1 and 4. By reversing the direction in which the soft magnetic bodies 43 are displaced from each other with respect to the first or second soft magnetic body 40 or 41, the second and third magnetoresistance effect elements 2 and 3 can be formed. It is thus possible to form a bridge circuit in which the difference in the TCR and the difference in the midpoint potential among the magnetoresistance effect elements are small (preferably zero).

By rotating the arrangements of the magnetoresistance effect elements and the soft magnetic bodies shown in FIG. 3A, 4, or 8 by 90°, it is possible to form a magnetic sensor that can detect an external magnetic field applied from the Y direction.

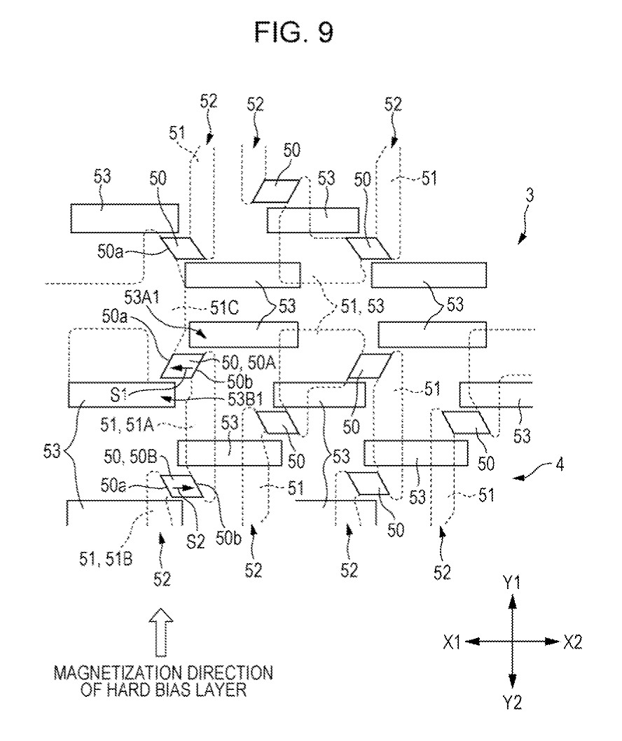

FIG. 9 is an enlarged partial plan view illustrating a portion designated by IV shown in FIG. 1 according to another embodiment. The configuration shown in FIG. 9 is more preferable than that shown in FIGS. 3A and 4.

As shown in FIG. 9, each of the magnetoresistance effect elements 3 and 4 includes a plurality of element portions 50 and hard bias layers 51. In FIG. 9, the hard bias layers 51 are indicated by broken lines. The multilayered structure of each of the element portions 50 is similar to that shown in FIG. 6.

In the embodiment shown in FIG. 9, a plurality of element linked bodies 52 extending in the Y1-Y2 direction are formed. The element linked bodies 52 are disposed in the X1-X2 direction with a space therebetween. The end portions on the Y1 side or the end portions on the Y2 side of the element linked bodies 52 are connected with each other with a connecting portion 53 of the hard bias layer 51. With this configuration, the magnetoresistance effect elements 3 and 4 are formed in a meandering shape.

Each of the element linked bodies 52 includes a plurality of element portions 50 and hard bias layers 51. The plurality of element portions 50 are disposed in the Y1-Y2 direction with a space therebetween. The hard bias layers 51 extend in the Y1-Y2 direction and are alternately disposed between end portions 50a on the X1 side of the element portions 50 and between end portions 50b on the X2 side of the element portions 50.

This configuration will be described more specifically by taking element portions 50A and 50B shown in FIG. 9 as examples. An end portion 50b on the X2 side of the element portion 50A and an end portion 50b on the X2 side of the element portion 50B are connected to each other with a hard bias layer 51A extending in the Y1-Y2 direction therebetween. An end portion 50a on the X1 side of the element portion 50B is connected to an end portion on the X1 side of another element portion (not shown) with a hard bias layer 51B extending in the Y1-Y2 direction therebetween. An end portion 50a on the X1 side of the element portion 50A is connected to an end portion 50a on the X1 side of the element portion 50 forming the magnetoresistance effect element 3 with a hard bias layer 51C (which forms part of the output terminal 8 shown in FIG. 1) extending in the Y1-Y2 direction.

If the magnetization direction of the hard bias layer 51 is the Y1 direction, a bias magnetic field S1 oriented in the X1 direction acts on the element portion 50A, while a bias magnetic field S2 oriented in the X2 direction acts on the element portion 50B. In this manner, the bias magnetic fields S1 and S2 oriented in the opposite directions are applied to the element portions 50A and 50B, respectively.

In the embodiment shown in FIG. 9, as well as in the foregoing embodiment, the plurality of soft magnetic bodies 53 are displaced from one another in the X1-X2 direction and are disposed on one and the other sides of each element portion 50 in the Y1-Y2 direction.

The insulating layer 21 shown in FIG. 5 intervenes between each of the magnetoresistance effect elements 3 and 4 and the soft magnetic layer 53.

In the embodiment shown in FIG. 9, the pinned magnetization directions P of the pinned magnetic layers 34 of the element portions 50A and 50B are the same. However, the directions of the bias magnetic fields 51 and S2 are opposite, and thus, the magnetization direction of the free magnetic layer 36 (see FIG. 6) of the element portion 50A is opposite to that of the element portion 50B. Accordingly, when the sensitivity of the element portions 50 is changed due to the action of an external magnetic field, the direction in which the sensitivity of the element portion 50A is shifted is opposite to the direction in which the sensitivity of the element portion 50B is shifted. Thus, a variation in the sensitivity in the overall magnetoresistance effect elements 3 and 4 (the same applies to the magnetoresistance effect elements 1 and 2) including the element portions 50A and 50B can be made small. As a result, in the embodiment shown in FIG. 9, the linearity of output characteristics can be effectively improved.

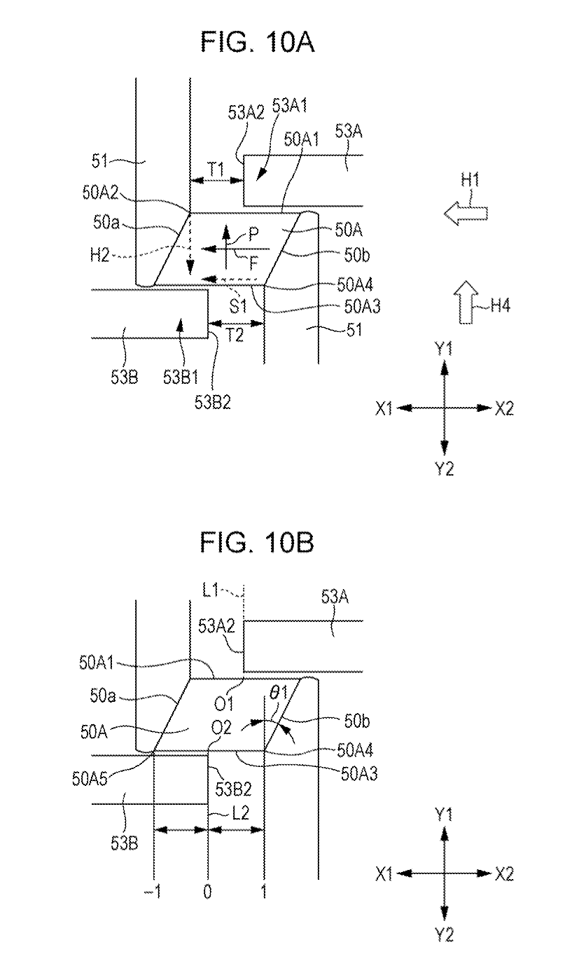

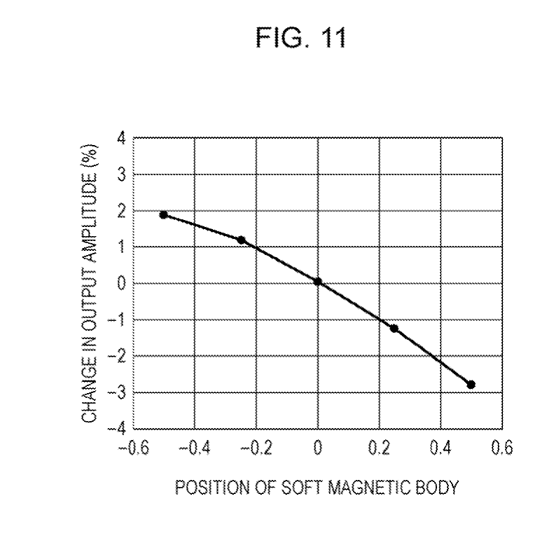

As shown in FIG. 9, the end portion 50a on the X1 side and the end portion 50b on the X2 side of the element portion 50A and those of the element portion 50B are obliquely tilted from extending in the Y1-Y2 direction so as to be tilted toward the X1-X2 direction. The end portions 50a on the X1 side and the end portions 50b on the X2 side are linearly formed. The angle θ1 of tilt (see FIG. 10B) of the end portion 50a on the X1 side or that of the end portion 50b on the X2 side ranges about from 20° to 70°. By forming the end portion 50a on the X1 side and the end portion 50b on the X2 side as tilted surfaces in this manner, the bias magnetic fields S1 and S2 can be correctly applied to the element portions 50 in the X1-X2 direction from the hard bias layers 51 which are magnetized in the Y1-Y2 direction.

As shown in FIG. 9, the direction in which the end portion 50a on the X1 side and the end portion 50b on the X2 side of the element portion 50A are tilted is opposite to that in the element portion 50B. With this arrangement, the hard bias layers 51 extending in the Y1-Y2 direction can be correctly disposed alternately between the end portions 50a on the X1 side of the element portions 50A and 50B and between the end portions 50b on the X2 side of the element portions 50A and 50B, and also, the bias magnetic fields 51 and S2 in the X1-X2 direction can be correctly supplied to the element portions 50A and 50B, respectively. With this arrangement, the magnetoresistance effect elements formed in a meandering shape can be naturally disposed in a limited narrow area.

In the embodiment shown in FIG. 9, as well as in the embodiment shown in FIGS. 3A and 4, for example, in the magnetoresistance effect element 4, a front end portion 53A1 of the soft magnetic body 53 disposed on the Y1 side of each element portion 50 opposes the element portion 50 in the Y1-Y2 direction as viewed from above, and a back end portion 53B1 of the soft magnetic body 53 disposed on the Y2 side of each element portion 50 opposes the element portion 50 in the Y1-Y2 direction as viewed from above. The direction in which the soft magnetic bodies 53 are displaced from each other with respect to the element portions 50 of the magnetoresistance effect element 3 is opposite to the direction in which the soft magnetic bodies 53 are displaced from each other with respect to the element portions 50 of the magnetoresistance effect element 4.

In the embodiment shown in FIG. 9, as well as in the embodiment shown in FIGS. 3A and 4, the plurality of soft magnetic bodies 53 are disposed between adjacent element linked bodies 52 and are used for both the adjacent element linked bodies 52.

A preferable arrangement of the soft magnetic bodies 53 with respect to the element portions 50 will be discussed below with reference to FIGS. 10A and 10B. FIGS. 10A and 10B are enlarged partial plan views illustrating the element portion 50A shown in FIG. 9.

As shown in FIG. 10A, a first soft magnetic body 53A is disposed on the Y1 side of the element portion 50A, while a second soft magnetic body 53B is disposed on the Y2 side of the element portion 50A. The external magnetic field H1 is applied in the X1 direction, and is then changed to the external magnetic field H2 in the Y1-Y2 direction (direction of the sensitivity axis) between the front end portion 53A1 of the first soft magnetic body 53A and the back end portion 53B1 of the second soft magnetic body 53B.

As shown in FIG. 10A, an X1-side front surface 53A2 of the front end portion 53A1 of the first soft magnetic body 53A is positioned in the X2 direction so as to be spaced apart from an X1-side side edge 50A2 of a Y1-side first side surface 50A1 of the element portion 50A. As viewed from above, a gap T1 in the X1-X2 direction is provided between the front surface 53A2 and the X1 side edge 50A2.

Additionally, as shown in FIG. 10A, an X2-side back surface 53B2 of the back end portion 53B1 of the second soft magnetic body 53B is positioned in the X1 direction so as to be spaced apart from an X2-side side edge 50A4 of a Y2-side second side surface 50A3 of the element portion 50A. As viewed from above, a gap T2 in the X1-X2 direction is provided between the back surface 53B2 and the X2 side edge 50A4.

As shown in FIG. 10A, the first and second soft magnetic bodies 53A and 53B are displaced from each other in the X1-X2 direction such that they do not oppose each other in the Y1-Y2 direction.

Assume that, as shown in FIG. 10A, a disturbance magnetic field H4, which is orthogonal to the external magnetic field H1, is now applied in the Y1 direction. In this case, the influence of the disturbance magnetic field H4 on the bias magnetic field S1, which is supplied to the element portion 50A, varies depending on the arrangement of the soft magnetic bodies 53A and 53B with respect to the element portion 50A.

This will be described more specifically. If the area over which the soft magnetic bodies 53A and 53B oppose each other with the element portion 50A therebetween increases, the disturbance magnetic field H4 entering the soft magnetic bodies 53A and 53B is more likely to flow into the element portion 50A, thereby influencing more adversely the bias magnetic field S1. Conversely, if the soft magnetic bodies 53A and 53B are excessively separated from each other in the X1-X2 direction, the disturbance magnetic field H4 is more likely to flow into the element portion 50A. Accordingly, in this embodiment, as shown in FIG. 10A, the front surface 53A2 of the front end portion 53A1 of the first soft magnetic body 53A is separated, in the X2 direction, from the X1 side edge 50A2 of the first side surface 50A1 of the element portion 50A with the gap T1 therebetween. As shown in FIG. 10A, the back surface 53B2 of the back end portion 53B1 of the second soft magnetic body 53B is separated, in the X1 direction, from the X2 side edge 50A4 of the second side surface 50A3 of the element portion 50A with the gap T2 therebetween. Additionally, the first and second soft magnetic bodies 53A and 53B are displaced from each other in the X1-X2 direction such that they do not oppose each other in the Y1-Y2 direction.

As shown in FIG. 10B, the front surface 53A2 of the first soft magnetic body 53A is positioned on a line L1 that extends in the Y1-Y2 direction from the center O1 of the first side surface 50A1 of the element portion 50A in the widthwise direction, and the back surface 53B2 of the second soft magnetic body 53B is positioned on a line L2 that extends in the Y1-Y2 direction from the center O2 of the second side surface 50A3 of the element portion 50A in the widthwise direction. In this state, the positions of the soft magnetic bodies 53A and 53B are considered to be 0. Then, a change in the output amplitude was measured while shifting the second soft magnetic body 53B in the X1-X2 direction. More specifically, when a disturbance magnetic field is applied in the Y direction while detecting magnetic flux components in the X direction, errors occur in the calculation of the directions. In this case, a change in the amplitude of such errors was measured.

As shown in FIG. 10B, the position of the back surface 53B2 of the second soft magnetic body 53B upon being shifted to such a degree as to oppose an X1 side edge 50A5 of the second side surface 50A3 of the element portion 50A is set to be −1, and the position of the back surface 53B2 of the second soft magnetic body 53B upon being shifted to such a degree as to oppose the X2 side edge 50A4 of the second side surface 50A3 of the element portion 50A is set to be 1.

FIG. 11 shows that, as the second soft magnetic body 53B is shifted away from the widthwise center in the X1-X2 direction, a change in the output amplitude increases. If the second soft magnetic body 53B is fixed in place and the first soft magnetic body 53A is shifted in the X1-X2 direction, a change in the output amplitude also increases, as in the result shown in FIG. 11.

Accordingly, the front surface 53A2 and the back surface 53B2 of the first and second soft magnetic bodies 53A and 53B, respectively, are respectively positioned on the lines L1 and L2 that extend in the Y1-Y2 direction from the widthwise centers of the first and second side surfaces 50A1 and 50A3 of the element portion 50A. With this arrangement, the resistance to the disturbance magnetic field can be effectively improved.

It is also suitable that the front surface 53A2 and the back surface 53B2 of the first and second soft magnetic bodies 53A and 53B, respectively, are positioned on lines drawn from the midpoint (widthwise and lengthwise center) of the element portion 50A in the Y1-Y2 direction.

The above-described positional arrangement of the soft magnetic bodies can also be applied to the configuration shown in FIGS. 3A and 4.

What is claimed is:

1. A magnetic sensor comprising:
a magnetoresistance effect element configured to be formed by stacking a magnetic layer and a non-magnetic layer on a substrate so as to exhibit a magnetoresistance effect; and
soft magnetic bodies configured to change a direction of an external magnetic field applied from a direction orthogonal to a direction of a sensitivity axis of the magnetoresistance effect element into the direction of the sensitivity axis and to supply the external magnetic field to the magnetoresistance effect element, the soft magnetic bodies being disposed so as not to be in contact with the magnetoresistance effect element, wherein:
a Y direction of the magnetoresistance effect element is the direction of the sensitivity axis, and the soft magnetic bodies are each disposed on one side and the other side of the magnetoresistance effect element in the Y direction, among the soft magnetic bodies, a first soft magnetic body included in the softmagnetic bodies disposed on the one side of the magnetoresistance effect element and a second soft magnetic body included in the softmagnetic bodies disposed on the other side of the magnetoresistance effect element being displaced from each other in an X direction, which is orthogonal to the Y direction, so that the X direction of an external magnetic field applied from the X direction is changed to the Y direction between the first and second soft magnetic bodies and the external magnetic field flows into the magnetoresistance effect element; and
the magnetoresistance effect element includes an element linked body extending in the X direction, the element linked body including a plurality of element portions disposed with a space between the element portions in the X direction and an electrode layer disposed between the element portions, a soft magnetic body being disposed on each of one side and the other side of each of the element portions so that the soft magnetic bodies disposed on the one side and the other side of each of the element portions are displaced from each other in the X direction.

2. The magnetic sensor according to claim 1, wherein the first and second soft magnetic bodies are displaced from each other in the X direction so that the first and second soft magnetic bodies do not oppose each other in the Y direction.

3. The magnetic sensor according to claim 2, wherein the first and second soft magnetic bodies each include an end portion at which the direction of the external magnetic field is changed to the direction of the sensitivity axis between the first and second soft magnetic bodies, the end portion of the first soft magnetic body including an X1 end surface facing in an X1 direction, the X1 end surface being positioned, in an X2 direction, so as to be spaced apart from an X1 side edge portion of a first side surface, the first side surface being the one side of the magnetoresistance effect element, the end portion of the second soft magnetic body including an X2 end surface facing in the X2 direction, the X2 end surface being positioned, in the X1 direction, so as to be spaced apart from an X2 side edge portion of a second side surface, the second side surface being the other side of the magnetoresistance effect element.

4. The magnetic sensor according to claim 3, wherein the X1 end surface of the first soft magnetic body is positioned on a line that extends in the Y direction from an X-direction-widthwise center of the first side surface of the magnetoresistance effect element, and the X2 end surface of the second soft magnetic body is positioned on a line that extends in the Y direction from an X-widthwise center of the second side surface of the magnetoresistance effect element.

5. The magnetic sensor according to claim 1, wherein, when one side in the X direction is taken to be a front side and the other side in the X direction is taken to be a back side, a front end portion of a soft magnetic body disposed on the one side of each of the element portions opposes the element portion in the Y direction, and a back end portion of a soft magnetic body disposed on the other side of each of the element portions opposes the element portion in the Y direction, or the back end portion of a soft magnetic body disposed on the one side of each of the element portions opposes the element portion in the Y direction, and the front end portion of a soft magnetic body disposed on the other side of each of the element portions opposes the element portion in the Y direction.

6. The magnetic sensor according to claim 5, wherein the element linked body is provided in a plurality, the plurality of element linked bodies being disposed with a space between the element linked bodies in the Y direction, the element linked bodies being formed in a meandering shape by connecting end portions of the element linked bodies to each other, and the soft magnetic bodies are disposed between the element linked bodies with a space between the soft magnetic bodies in the X direction, each of the soft magnetic bodies being used for the element linked bodies positioned adjacent to each other.

7. The magnetic sensor according to claim 4, wherein the magnetoresistance effect element includes a plurality of element portions disposed with a space between the element portions in the Y direction and hard bias layers positioned between the element portions so as to connect the element portions, and the hard bias layers are disposed alternately between X1 end portions of the element portions and X2 end portions of the element portions so that a bias magnetic field applied from the X direction flows into the element portions and so that a direction of the bias magnetic field flowing into one of the element portions connected to each other with the hard bias layer is opposite to a direction of the bias magnetic field flowing into the other one of the element portions connected to each other with the hard bias layer, and a soft magnetic body is disposed on each of one side and the other side of each of the element portions in the Y direction so that the soft magnetic bodies disposed on the one side and the other side of each of the element portions are displaced from each other in the X direction.

8. The magnetic sensor according to claim 7, wherein the X1 end portions and the X2 end portions of the element portions are obliquely tilted from extending in the Y direction so as to be tilted toward the X direction.

9. The magnetic sensor according to claim 8, wherein, when one side in the X direction is taken to be a front side and the other side in the X direction is taken to be a back side, a front end portion of a soft magnetic body disposed on the one side of each of the element portions opposes the element portion in the Y direction, and a back end portion of a soft magnetic body disposed on the other side of each of the element portions opposes the element portion in the Y direction, or the back end portion of a soft magnetic body disposed on the one side of each of the element portions opposes the element portion in the Y direction, and the front end portion of a soft magnetic body disposed on the other side of each of the element portions opposes the element portion in the Y direction.

10. The magnetic sensor according to claim 9, wherein the element linked body is provided in a plurality, the plurality of element linked bodies extending in the Y direction and being disposed with a space between the element linked bodies in the X direction, each of the plurality of element linked bodies including the element portions and the hard bias layers, the element linked bodies being formed in a meandering shape by connecting end portions of the element linked bodies to each other, and the plurality of soft magnetic bodies are disposed between the element linked bodies, each of the soft magnetic bodies being used for the element linked bodies positioned adjacent to each other.

11. The magnetic sensor according to claim 1, wherein:
the magnetoresistance effect element includes an element linked body, the element linked body including a plurality of first element portions, a plurality of second element portions, and an electrode layer connecting the first and second element portions, the plurality of first element portions being disposed with a space between the first element portions in the X direction, the plurality of second element portions being displaced from the plurality of first element portions in the X direction and being disposed with a space between the second element portions in the Y direction, which is orthogonal to the X direction;
the Y direction of the first and second element portions is the direction of the sensitivity axis, and a soft magnetic body is disposed on each of one and the other sides of each of the first and second element portions such that the soft magnetic body opposes the first or second element portion in the Y direction in a non-contact manner; and
the soft magnetic bodies disposed on the one side and the other side of each of the first and second element portions are displaced from each other in the X direction so that a direction of an external magnetic field applied from the X direction is changed to the Y direction between the soft magnetic bodies and the external magnetic field flows into each of the first and second element portions.

12. The magnetic sensor according to claim 11, wherein the element linked body is provided in a plurality, the plurality of element linked bodies being disposed with a space between the element linked bodies in the Y direction, end portions of the element linked bodies being connected to each other, and, between the element linked bodies, the soft magnetic bodies are disposed with a space between the soft magnetic bodies in the X direction, each of the soft magnetic bodies being used for the element linked bodies positioned adjacent to each other.

13. The magnetic sensor according to claim 1, wherein:
the magnetoresistance effect element is provided in a plurality, the magnetic sensor is formed by a bridge circuit including first, second, third, and fourth magnetoresistance effect elements;
the first and third magnetoresistance effect elements are connected to an input terminal, while the second and fourth magnetoresistance effect elements are connected to a ground terminal, and a first output terminal is connected between the first and second magnetoresistance effect elements, while a second output terminal is connected between the third and fourth magnetoresistance effect elements;
the first, second, third, and fourth magnetoresistance effect elements are formed by an identical film structure and pinned magnetization directions of pinned magnetic layers provided for the individual first, second, third, and fourth magnetoresistance effect elements are identical; and
an arrangement of the soft magnetic bodies with respect to the first and fourth magnetoresistance effect elements is different from an arrangement of the soft magnetic bodies with respect to the second and third magnetoresistance effect elements so that a direction of an external magnetic field flowing into the first and fourth magnetoresistance effect elements is opposite to a direction of an external magnetic field flowing into the second and third magnetoresistance effect elements.

14. The magnetic sensor according to claim 13, wherein a Y direction of each of the first, second, third, and fourth magnetoresistance effect elements is the direction of the sensitivity axis, and a soft magnetic body is disposed on each of one side and the other side of each of the first, second, third, and fourth magnetoresistance effect elements in the Y direction, and a soft magnetic body disposed on the one side of each of the first, second, third, and fourth magnetoresistance effect elements and a soft magnetic body disposed on the other side of each of the first, second, third, and fourth magnetoresistance effect elements are displaced from each other in the X direction so that the X direction of an external magnetic field applied from the X direction is changed to the Y direction between the soft magnetic bodies disposed on the one and the other sides of each of the first, second, third, and fourth magnetoresistance effect elements and the external magnetic field flows into each of the first, second, third, and fourth magnetoresistance effect element, and a direction in which the soft magnetic bodies disposed on the one side and the other side of each of the first and fourth magnetoresistance effect elements are displaced from each other with respect to the first and fourth magnetoresistance effect elements is opposite to a direction in which the soft magnetic bodies disposed on the one side and the other side of each of the second and third magnetoresistance effect elements are displaced from each other with respect to the second and third magnetoresistance effect elements.

15. The magnetic sensor according to claim 14, wherein:
each of the first, second, third, and fourth magnetoresistance effect elements includes an element linked body extending in the X direction, the element linked body including a plurality of element portions disposed with a space between the element portions in the X direction and an electrode layer disposed between the element portions; and
when one side in the X direction is taken to be a front side and the other side in the X direction is taken to be a back side, in the first and fourth magnetoresistance effect elements, a front end portion of a soft magnetic body disposed on the one side of each of the element portions forming the first and fourth magnetoresistance effect elements opposes the element portion in the Y direction, while a back end portion of a soft magnetic body disposed on the other side of each of the element portions opposes the element portion in the Y direction, and in the second and third magnetoresistance effect elements, the back end portion of a soft magnetic body disposed on the one side of each of the element portions forming the second and third magnetoresistance effect elements opposes the element portion in the Y direction, while the front end portion of a soft magnetic body disposed on the other side of each of the element portions opposes the element portion in the Y direction.
